(19) United States
(12) Patent Application Publication
(10) Pub. No.: US 2006/0249859 A1
(43) Pub. Date: Nov. 9, 2006

(54) Metrology system and method for stacked wafer alignment

(76) Inventors: Travis M. Eiles, Beaverton, OR (US); Shriram Ramanathan, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/123,698

(22) Filed: May 5, 2005

(51) Int. Cl. H01L 23/544

(52) U.S. Cl. 257/797

(57) ABSTRACT

Using imaging techniques to determine if stacked wafers are in proper alignment. An infrared radiation source and an infrared camera are positioned on opposing sides of a stacked wafer. The infrared radiation source emits infrared radiation that penetrates and passes through the stacked wafer. The infrared radiation is then captured by the infrared camera. Fiducial marks that were previously patterned on each wafer of the stack are exposed in an image produced by the captured infrared radiation. The degree of alignment of the wafers can be measured using the fiducial marks exposed in the image.

### BACKGROUND

Current technology for fabricating integrated circuits produces a two-dimensional structure. For a given process technology, an increase in performance and functionality of an optimized design is accompanied by a corresponding increase in die size. However, die size is not, in practice, unbounded. As both processor frequencies and die size increase, a growing number of clock cycles will be necessary for communications across a larger sized die, and this interconnect delay may be unsuitable for high performance applications. Moreover, although scaling down of transistor dimensions can make the transistors faster, connecting them requires an increasing number of wires. A possible solution to meeting the wire demands is to decrease the wire dimensions, but this approach can degrade their performance by increasing delay.

One solution that integrated circuit manufacturers are investigating is three-dimensional (3-D) structures produced by wafer stacking. This is driven in part by the demand for smaller personal computers (e.g., laptop computers) and the increasing popularity of hand-held computing devices—e.g., mobile phones, tablet computers, personal digital assistants (PDAs), and the like—which are pushing manufacturers to develop integrated circuit (IC) devices having a smaller form factor (e.g., decreased die area, volume, and weight).

Wafer stacking also enables system-on-chip (SOC) technologies. Previously, incompatible process flows inhibited the integration of different technologies—e.g., optical and electrical, radio frequency (RF) and logic, memory and logic, etc.—onto a single die. With wafer stacking, these different technologies can be produced on separate wafers that can be stacked and interconnected.

Wafer stacking generally involves the bonding together of two or more semiconductor wafers upon which integrated circuitry has been formed. The wafer stack is subsequently cut into separate “stacked die,” each stacked die having multiple layers of integrated circuitry. Wafer stacking technology offers a number of potential benefits. For example, IC devices formed by wafer stacking techniques may provide enhanced performance and functionality (e.g., SOC solutions) while lowering costs and improving form factors. System-on-chip architectures formed by wafer stacking can enable high bandwidth connectivity between stacked die with dissimilar technologies—e.g., logic circuitry and dynamic random access memory (DRAM)—that otherwise have incompatible process flows. Also, by using 3-D technologies, smaller die sizes can be achieved resulting in a significant decrease in interconnect delays, which increases performance while decreasing power and, potentially, cost.

Wafer stacking does, however, present a number of technological challenges. To achieve the potential benefits of wafer stacking described above, while also maintaining reliability, a number of issues need to be addressed, including the alignment metrology of 3-D wafer stacking. Overlay metrology is a critical part of wafer processing as it measures the proper alignment of subsequent pattern layers on the wafer. In 3-D wafer stacking, the two wafers are bonded together on the patterned faces. An overlay metrology is needed to ensure proper alignment in this bonding step. While this type of bonding alignment metrology is analogous to what is done in wafer processing, it requires a completely new method since there are no patterned features open to the line of sight.

One conventional method for aligning-stacked wafers utilizes an infrared laser scanning microscope. This method, however, does not work when the wafers are highly doped due to the very high absorption of the laser light in the microscope. Since most IC manufacturers use highly doped wafers for their advanced microprocessors, another method is required.

### BRIEF DESCRIPTION OF THE DRAWINGS

FIG. 1 illustrates a side view and a plan view of a semiconductor wafer having fiducial marks.

FIG. 2 illustrates two semiconductor wafers stacked and bonded together.

FIG. 3 illustrates a metrology tool in accordance with an implementation of the invention.

FIG. 4 is a method of measuring the alignment of stacked wafers in accordance with an implementation of the invention.

### DETAILED DESCRIPTION

Described herein are systems and methods of using imaging techniques to measure the accuracy of the alignment of at least two stacked semiconductor wafers. In implementations of the invention, an infrared radiation source and an infrared camera are positioned on opposing sides of a stacked wafer. The infrared radiation source emits infrared radiation that penetrates and passes through the stacked wafer. The infrared radiation is then captured by the infrared camera. Alignment marks or fiducials that were previously patterned on each wafer of the stack are exposed in an image produced by the captured infrared radiation. The degree of alignment of the wafers can be measured using the fiducials exposed in the image.

In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

One conventional process for determining the degree of alignment of stacked semiconductor wafers uses a sensitive infrared camera with front-side illumination. This process is adequate for lightly doped semiconductor wafers that are thin. It has been shown, however, that a sensitive infrared camera with front-side illumination cannot image metallic structures through full-thickness wafers. This is at least partially due to the high degree of radiation reflection coming from the air-silicon interface on the back of the wafer.

A conventional process using a laser scanning microscope has proven successful for lightly doped semiconductor wafers as well. Similar to the process above, however, the laser scanning microscope proved to be ineffective in imaging metal structures through full-thickness and highly doped semiconductor wafers.

Implementations of the invention allow buried alignment marks or fiducials within stacked, highly-doped semiconductor wafers to be imaged by an infrared camera. The imaged alignment marks or fiducials can then be used to measure the degree of alignment of the stacked semiconductor wafers. The alignment marks or fiducials must be produced on the patterned surface of each semiconductor wafer prior to bonding.

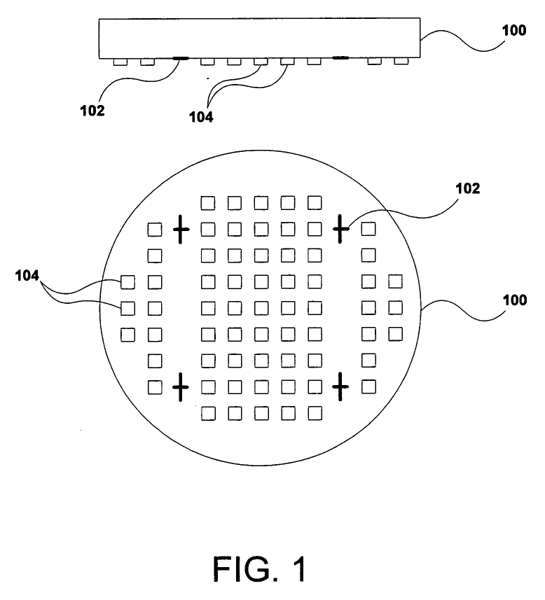

FIG. 1 illustrates a side view and a plan view of a semiconductor wafer 100 having fiducial marks 102. The semiconductor wafer 100 contains typical integrated circuit components, including but not limited to transistors, capacitors, and metal interconnects (not shown). The semiconductor wafer 100 may also include one or more electrical contacts 104 on its face, including but not limited to bond pads, vias, plugs, copper bumps, solder balls, and other forms of interconnects. In most implementations the semiconductor wafer 100 will be highly doped with ions. The semiconductor wafer 100 may contain at least one of a number of technologies, including but not limited to optical, electrical, RF, logic, and memory technologies.

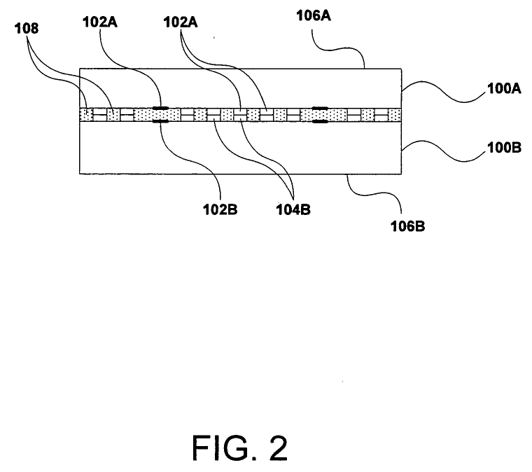

FIG. 2 illustrates two semiconductor wafers 100A and 100B stacked and bonded together. Both semiconductor wafers 100A and 100B are highly doped and have fiducial marks 102A and 102B that are patterned on the semiconductor wafers 100 prior to bonding. Both semiconductor wafers 100A and 100B may also include electrical contacts 104A and 104B. One or both of the semiconductor wafers may be relatively thick, with a thickness that generally ranges from 0.5 mm to 1.0 mm. In the implementation shown in FIG. 2, semiconductor wafer 100B is relatively thicker than semiconductor wafer 100A and may have a thickness that is around 0.75 mm. In implementations of the invention, both semiconductor wafers 100 are polished on their respective backsides 106A and 106B to minimize light scattering. If the wafers 100 are not polished, the rough finish causes a great deal of scattering that reduces the amount of radiation penetrating through the wafer to the infrared camera.

The semiconductor wafer stack 100A/B may be bonded using conventional methods and techniques. For example, in some implementations, an adhesive layer may be used to bond the semiconductor wafers 100. In some implementations, electrical contacts 104 (i.e., bond pads or solder balls) on the face of each semiconductor wafer 100 may be coupled and bonded together using known processes such as thermo-compression processes or reflow processes (e.g., a controlled collapse chip connection process). A filler material 108 may be placed into any air gap between the bonded wafers 100 to stabilize and passivate any exposed structures and surfaces. In some implementations, an interposer layer may be used between the stacked semiconductor wafers 100.

As stated above, an infrared camera using front-side illumination of a full thickness, highly-doped semiconductor wafer is generally incapable of imaging any metallic structures. This is due at least in part to the high degree of reflection coming from the air-silicon interface on the backside of the semiconductor wafer. A laser scanning microscope that successfully imaged low-doped test wafers also proved to be ineffective in imaging any metal structures through a full-thickness, highly-doped semiconductor wafer.

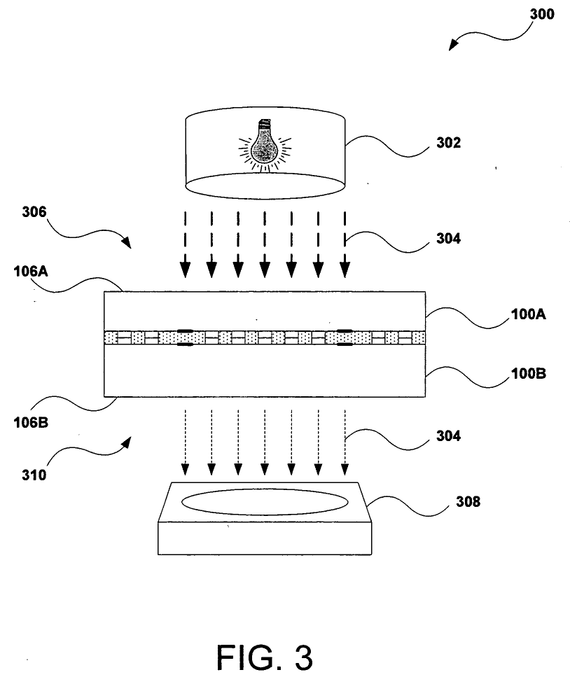

Therefore, in accordance with an implementation of the invention, a metrology tool for measuring the alignment of stacked semiconductor wafers includes a sensitive infrared camera using backside illumination. FIG. 3 illustrates a metrology tool 300 constructed in accordance with an implementation of the invention. The metrology tool 300 includes a radiation source 302. In some implementations, the radiation source 302 may consist of an infrared light source (e.g., an infrared lamp) that is capable of emitting infrared radiation 304. In some implementations, the radiation source 302 emits infrared radiation 304 with a wavelength that ranges from 1.0 to 1.5 microns, which is the wavelength range at which highly doped semiconductor wafers 100 are partially transparent. In other implementations, the radiation source 302 may consist of an infrared laser source capable of emitting infrared radiation 304 in the same wavelength range of 1.0 to 1.5 microns. Regardless of whether a lamp or a laser is used, the radiation source 302 must be sufficiently powerful to generate infrared radiation 304 that can penetrate completely through the semiconductor wafer stack 100A/B.

In one implementation, a standard 100 watt microscope lamp may be used when the light is condensed onto the wafer stack 100A/B using a standard microscope objective. For acceptable results, the light may be carefully aligned with the optical axis of the imaging camera. In other implementations, a focused or a non-focused laser light may be used.

The radiation source 302 is oriented on a first side 306 of the stacked semiconductor wafers 100A/B such that the radiation source 302 is substantially directed towards the backside 106 of either semiconductor wafer 100A or semiconductor wafer 100B. For instance, in the implementation of FIG. 3, the radiation source 302 is shown illuminating the backside 106A of semiconductor wafer 100A. The stacked semiconductor wafers 100A/B may be held in place by a conventional wafer mount.

The metrology tool 300 also includes a radiation collector 308 that corresponds to the radiation source 302. For example, the radiation collector 308 may consist of photodiodes that are capable of capturing the type of radiation emitted by the radiation source 302. If the radiation source 302 is emitting a particular wavelength of infrared radiation 304, then the radiation collector 308 uses photodiodes that are capable of capturing that wavelength of infrared radiation 304. In other implementations, the radiation collector 308 may consist of alternate technologies capable of capturing the type of radiation emitted by the radiation source 302, such as mercury cadmium telluride (HgCdTe) technology. In further implementations, any available forms of infrared-sensitive detectors may be used.

In one implementation, the radiation collector 308 may be an infrared camera that utilizes indium gallium arsenide (InGaAs) photodiodes. InGaAs is an alloy of gallium arsenide and indium arsenide. InGaAs photodiodes are sensitive to the low levels of infrared radiation emitted through heavily doped semiconductor wafers 100. InGaAs photodiodes are also sensitive to the infrared radiation 304 with a wavelength that ranges from 1.0 to 1.5 microns, which as stated above is the wavelength range where highly doped semiconductor wafers 100 are partially transparent. In fact, different types of InGaAs photodiodes can generally collect infrared radiation that ranges from 0.5 to 3.0 microns.

As shown in FIG. 3, in implementations of the invention, the radiation collector 308 is oriented on a second side 310 of the semiconductor wafer stack 100A/B, where the second side 310 is on an opposite side of the semiconductor wafer stack 100A/B from the first side 306. The radiation collector 308 is directed substantially towards the backside 106 of the semiconductor wafer stack 100A/B. This orientation allows the radiation collector 308 to capture infrared radiation 304 that has penetrated completely through the semiconductor wafer stack 100A/B. Accordingly, the radiation collector 308 captures transmissive radiation from the radiation source 302 rather than reflective radiation (as is the case with previously known imaging systems). In the implementation of FIG. 3, the transmissive infrared radiation 304 is captured as it exits the semiconductor wafer stack 100A/B through the backside 106B.

The amount of infrared radiation 304 that strikes the semiconductor wafer stack 100A/B on the backside 106A tends to be greater than the amount of infrared radiation that exits through the backside 106B. This is because portions of the infrared radiation 304 are lost as the radiation is reflected off the backside 106A and as the radiation is absorbed and scattered within the semiconductor wafer stack 100A/B. Despite these radiation losses, the metrology tool 300 is still functional because it generally takes only a modest amount of infrared radiation 304 to sufficiently outline the fiducial marks 102A and 102B.

Using the infrared radiation 304 captured by the radiation collector 308, an internal image of the semiconductor wafer stack 100A/B can be generated. This internal image will expose the fiducial marks 102A of the semiconductor wafer 100A and the fiducial marks 102B of the semiconductor wafer 100B. The accuracy of the wafer bonding process can then be measured using the imaged fiducial marks 102A and 102B.

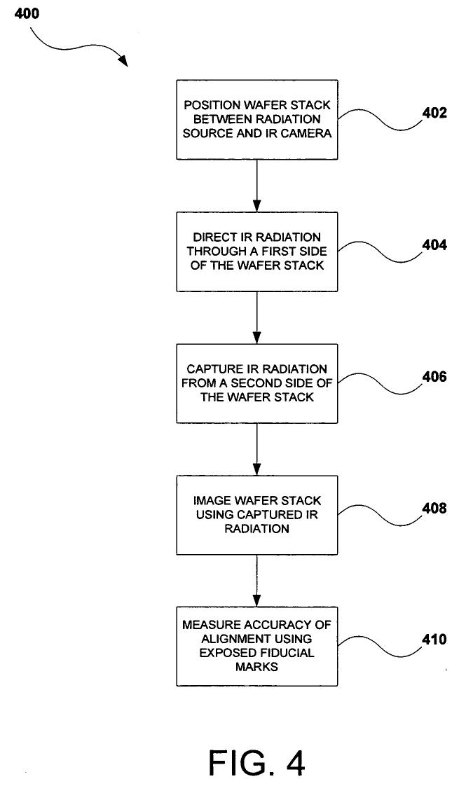

FIG. 4 describes a method 400 of measuring the accuracy of the alignment of stacked semiconductor wafers in accordance with an implementation of the invention. The semiconductor wafer stack 100A/B is first positioned between the radiation source 302 and the radiation collector 308, such as an infrared camera (402). The radiation source 302 is used to generate and direct infrared radiation towards a first side of the semiconductor wafer stack 100A/B, such as towards the backside 106A (404). After the infrared radiation penetrates completely through the semiconductor wafer stack 100A/B, the radiation collector 308 captures the infrared radiation from a second side of the semiconductor wafer stack 100A/B, such as from the backside 106B (406). Of course, in implementations of the invention the infrared radiation may be directed towards the backside 106B and then captured from the backside 106A.

With the captured infrared radiation, an internal portion of the semiconductor wafer stack 100A/B may be imaged (408), thereby exposing the fiducial marks 102 that were previously patterned on the semiconductor wafers 100A and 100B. The exposed fiducial marks 102 in the image may then be used to measure the accuracy of the alignment of the semiconductor wafers 100A and 100B (410).

In alternate implementations of the invention, the metrology tool 300 may be used to align a stack of two or more semiconductor wafers 100 prior to the wafers being bonded together. In such an implementations, after the accuracy of the alignment is measured and determined to be sufficient using the metrology tool 300, the wafers 100 may then be bonded together. In some implementations, the accuracy of the alignment may be re-tested with the metrology tool 300 after the bonding process to determine whether the bonding process caused the wafers 100 to become misaligned.

In another implementation of the invention, the metrology tool 300 may be used to measure the accuracy of the alignment of individual die stacks rather than wafer stacks. Die stacks may be formed by stacking together two individual dies, by stacking two wafers and then singulating the die stack, or by stacking a die and a wafer. The metrology tool 300 may be used before the die stack has been bonded to make sure that the dies are sufficiently aligned or it may be used after the die stack has been bonded to check the accuracy of the alignment.

In yet another implementation of the invention, the metrology tool 300 may be used for imaging the backside 106 of at least one semiconductor wafer 100 for patterning backside vias (not shown). Backside vias extend through the silicon of the semiconductor wafer 100 and are coupled to devices and/or interconnects within the semiconductor wafer 100. In one implementation, the semiconductor wafer 100 may be thinned using a process such as chemical mechanical polishing. The metrology tool 300 may then be used to image interconnect layers within the thinned semiconductor wafer 100. Backside vias may then be patterned and fabricated based on the image using known photolithography and metallization techniques. The backside vias may be used to provide electrical interconnections that include but are not limited to power delivery and signal delivery.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a mount adapted to hold a semiconductor wafer stack at a location;
a radiation source oriented on a first side of the location; and
a radiation collector oriented on a second side of the location, wherein the radiation collector is oriented to receive transmissive radiation from the radiation source.

2. The apparatus of claim 1, wherein the radiation source comprises an infrared lamp capable of emitting infrared radiation.

3. The apparatus of claim 2, wherein the infrared radiation has a wavelength that ranges from 1.0 to 1.5 microns.

4. The apparatus of claim 1, wherein the radiation source comprises an infrared laser source capable of emitting an infrared laser.

5. The apparatus of claim 4, wherein the infrared laser has a wavelength that ranges from 1.0 to 1.5 microns.

6. The apparatus of claim 1, wherein the radiation collector comprises an infrared camera.

7. The apparatus of claim 6, wherein the infrared camera comprises InGaAs photodiodes.

8. The apparatus of claim 1, wherein when a semiconductor wafer stack is held at the location by the mount, the radiation source is capable of directing radiation at a first backside of the semiconductor wafer stack, and the radiation collector is capable of receiving radiation from a second backside of the semiconductor wafer stack, wherein the radiation is received in a transmissive manner.

9. The apparatus of claim 1, wherein the semiconductor wafer stack comprises at least two semiconductor dies that are stacked.

10. The apparatus of claim 1, wherein the semiconductor wafer stack comprises a semiconductor die and a semiconductor wafer that are stacked.

11. An apparatus comprising:
an infrared radiation source capable of directing infrared radiation having a wavelength that ranges from 1.0 to 1.5 microns towards a first backside of a semiconductor wafer stack; and
an infrared radiation collector capable of receiving infrared radiation having a wavelength that ranges from 1.0 to 1.5 microns from a second backside of the semiconductor wafer stack, wherein the infrared radiation is received in a transmissive manner after it has passed through the semiconductor wafer stack.

12. The apparatus of claim 11, further comprising a mount to hold the semiconductor wafer stack.

13. The apparatus of claim 11, wherein the infrared radiation collector comprises an infrared camera having InGaAs photodiodes.

14. A method comprising:
directing radiation towards a first backside of a semiconductor wafer stack;
receiving the radiation from a second backside of the semiconductor wafer stack;
producing an image based at least in part on the received radiation; and
measuring the accuracy of the alignment of the semiconductor wafers in the stack based at least in part on the image.

15. The method of claim 14, wherein the radiation comprises infrared radiation.

16. The method of claim 15, wherein the infrared radiation has a wavelength that ranges from 1.0 to 1.5 microns.

17. The method of claim 14, wherein the radiation is received in a transmissive manner from the second backside.

18. The method of claim 14, wherein the producing of the image exposes a plurality of fiducial marks within the semiconductor wafer stack.

19. The method of claim 18, wherein the measuring of the accuracy of the alignment is based at least in part on the exposed fiducial marks.

20. A method comprising:
directing radiation towards a first backside of an unbonded semiconductor wafer stack;
receiving the radiation from a second backside of the unbonded semiconductor wafer stack;
producing an image based at least in part on the received radiation to expose a plurality of fiducial marks within the stack;
measuring the accuracy of the alignment of the semiconductor wafers in the stack based at least in part on the image and the fiducial marks; and
bonding the semiconductor wafers in the stack if the alignment of the semiconductor wafers is sufficiently accurate.

21. The method of claim 20, wherein the radiation comprises infrared radiation.

22. The method of claim 21, wherein the infrared radiation has a wavelength that ranges from 1.0 to 1.5 microns.

23. The method of claim 20, wherein the radiation is received in a transmissive manner from the second backside.

24. The method of claim 20, further comprising:
directing radiation towards the first backside of the newly bonded semiconductor wafer stack;
receiving the radiation from the second backside of the newly bonded semiconductor wafer stack;
producing an image based at least in part on the received radiation to expose the plurality of fiducial marks within the stack;
measuring the accuracy of the alignment of the semiconductor wafers in the stack based at least in part on the image and the fiducial marks to determine if the alignment of the semiconductor wafers is still sufficiently accurate after the bonding.

25. The method of claim 24, wherein the radiation comprises infrared radiation.

26. The method of claim 25, wherein the infrared radiation has a wavelength that ranges from 1.0 to 1.5 microns.

27. The method of claim 24, wherein the radiation is received in a transmissive manner from the second backside.

28. A method comprising:
directing radiation towards a first surface of a semiconductor wafer;
receiving the radiation from a second surface of the semiconductor wafer;
producing an image based at least in part on the received radiation to expose an interconnect layer within the semiconductor wafer; and
patterning the second surface of the semiconductor wafer to form backside vias based at least in part on the image and the exposed interconnect layer.

29. The method of claim 28, wherein the radiation comprises infrared radiation.

30. The method of claim 29, wherein the infrared radiation has a wavelength that ranges from 1.0 to 1.5 microns.

31. The method of claim 28, wherein the radiation is received in a transmissive manner from the second surface.

32. The method of claim 28, wherein the patterning of the second surface comprises using photolithography and metallization processes to define, etch, and form the backside vias.
